(19) United States
(12) Patent Application Publication
(10) Pub. No.: US 2025/0389763 A1
(43) Pub. Date: Dec. 25, 2025

(54) TEST SYSTEM FOR VEHICLE-MOUNTED ANTENNA

(71) Applicant: GENERAL TEST SYSTEMS INC., Shenzhen, Guangdong (CN)

(72) Inventors: Wei Yu, Shenzhen, Guangdong (CN); Li Qin, Shenzhen, Guangdong (CN)

(21) Appl. No.: 18/875,199

(22) PCT Filed: Nov. 22, 2022
(86) PCT No.: PCT/CN2022/133507

§ 371 Date: Dec. 16, 2024

(30) Foreign Application Priority Data
Jun. 17, 2022 (CN) 202210693196.1

(51) Int. Cl. G01R 29/08; G01R 31/00; G01R 35/00

(52) U.S. Cl. CPC G01R 29/0821; G01R 29/0878; G01R 31/006; G01R 35/007

(57) ABSTRACT

A test system for a vehicle-mounted antenna. In the test system, when a bearing face is connected to a reflecting plate or when the reflecting plate extends from the bearing face, the testing system for a vehicle-mounted antenna can be used for a semi-anechoic chamber test; and when the bearing face is not connected to the reflecting plate or when the reflecting plate is retracted into the bearing face, the test system for a vehicle-mounted antenna can be used for a fully anechoic chamber test. That is to say, the test system for a vehicle-mounted antenna not only has the fully anechoic chamber testing function, but also has the semi-anechoic chamber testing function, and the two functions can be conveniently switched by means of the mounting/removal or extension/retraction of the reflecting plate.

### CROSS-REFERENCE TO RELATED APPLICATION

The present disclosure claims priority to Chinese patent Application No. 202210693196.1, filed with the Chinese Patent Office on Jun. 17, 2022, entitled “TEST SYSTEM FOR VEHICLE-MOUNTED ANTENNA,” the whole contents of which are incorporated herein by reference.

### TECHNICAL FIELD

The present disclosure relates to the technical field of communication, and in particular to a test system for a vehicle-mounted antenna.

### BACKGROUND ART

The full-vehicle antenna is mounted on the full vehicle body, e.g., a vehicle antenna is mounted on the full car body, and a tank antenna is mounted on the full tank body. In the full vehicle state, the performance (such as antenna pattern and gain) of the full-vehicle antenna can be reflected more truly. The full-vehicle antenna that is mounted on the full vehicle body in the actual working environment is called a “vehicle-mounted antenna” below.

At present, the performance test of the vehicle-mounted antenna is usually carried out by a spherical test in related arts, wherein the test coordinate system of the spherical test is shown in FIG. 1. Several test systems can be used for the performance test of the vehicle-mounted antenna, including the full anechoic chamber test system, the semi-anechoic chamber test system, and the outdoor open-field test system. The 5G Automobile Association(5GAA) recognizes the above three test systems.

The full anechoic chamber test system includes a shielding body 111, and an absorbing material 112 (shown in FIG. 2), wherein the shielding body 111 is usually made of a metal plate for shielding external electromagnetic waves, thereby forming a test environment without external electromagnetic wave interference; and the absorbing material 112 is fully covered on an inner wall of the shielding body 111 for absorbing incident electromagnetic waves, so that the reflection of the electromagnetic waves inside the shielding body 111 can be reduced to the design requirements. The full anechoic chamber test system further includes a horizontally placed turntable 121, wherein the turntable is provided with a lifting machine 122; the lifting machine 122 can lift the full vehicle to be tested; and the turntable 121 drives the lifting machine 122 and the full vehicle to be tested to rotate together. The reason for providing the lifting machine 122 is that in the full anechoic chamber test, the test region can meet the quiet zone requirements only when there is a certain distance between the test region and the absorbing material 112 laid on the turntable 121. A measuring antenna 13 is arranged on a circular arc-shaped rail and can slide on the circular arc-shaped rail to sample on the circular arc-shaped track; or a plurality of measuring antennas 13 are fixedly mounted on an antenna support frame, and the plurality of measuring antennas 13 are distributed in a circular arc shape, wherein each measuring antenna is switched by an electronic switch, so as to perform the same sampling. During the test, the turntable 121 (including the lifting machine 122) drives the full vehicle to be tested to rotate, wherein the measuring antenna 13 moves on the circular arc-shaped rail and samples, or switch the plurality of measuring antennas 13 at different θ angles for sampling, so that the measuring antennas 13 can test the vehicle-mounted antenna at multiple spatial locations on one local spherical surface surrounding a local part of the full vehicle to be tested. The full anechoic chamber test system has the following characteristics. The center of the test coordinate system for the spherical test, i.e., the center of the circular arc-shaped track, is located directly above the rotation center of the turntable 121, and its height from the bottom surface of the shielding body 111 is H1; a radius of the circular arc is R; and the absorbing material 112 is arranged on the turntable 121. The full vehicle to be tested is located in a test coordinate system as shown in FIG. 3, wherein in the coordinate system, when the measuring antenna rotates to the positive direction of the Z-axis, θ in the test coordinate system shown in FIG. 1 is 0°; and when the measuring antenna rotates to the positive direction of the X-axis, 0-90°. In the full anechoic chamber test system, since the absorbing material 112 needs to be arranged below the full vehicle to be tested, the lifting machine 122 is configured to lift the full vehicle to be tested. The rotation range of the measuring antenna can exceed 90°. As long as the full vehicle to be tested is lifted high enough, the circular arc-shaped rail extends below the X-axis, and the θ angle can reach 120°.

Compared with the full anechoic chamber test system, the ground of the semi-anechoic chamber test system is not provided with the absorbing material 112, but other surfaces are provided with the absorbing material 112 (as shown in FIG. 4); a horizontally placed turntable 121 is also arranged in the semi-anechoic chamber test system; and the arrangement of the measuring antenna is similar to that in the full anechoic chamber test system. Different from the full anechoic chamber test system, the center of the circular arc-shaped track is located at the rotation center of the turntable 121, and is located on the upper surface of the turntable 121 (or a certain distance away from the upper surface), and the turntable 121 does not need to be provided with the lifting machine 122; and the full vehicle to be tested is placed on the turntable 121, and does not need to be lifted during the test. The semi-anechoic chamber test system has the following characteristics. The center of the circular arc-shaped track is located directly above the center of the turntable 121, and is located on the upper surface of the turntable. The turntable 121 is not provided with the absorbing material 112, and the full vehicle to be tested is placed directly on the turntable 121, i.e., the full vehicle to be tested is also located in the test coordinate system as shown in FIG. 3. No absorbing material 112 is arranged under or around the full vehicle to be tested, instead, materials for simulating the real ground is arranged on the turntable 121 and on the ground around the full vehicle to be tested according to the test requirements, so as to reflect the electromagnetic waves, which is configured to simulate the real use scenario of the full vehicle to be tested. In the semi-anechoic chamber test system, the rotation range of the measuring antenna can be up to 90°, and it cannot extend below the X-axis, so the measurement angle range cannot exceed 90°.

It should be noted that in the related arts, in addition to the test scenarios described above, other test scenarios can further be provided according to different test requirements, wherein the sampling trajectory of the measuring antenna is not circular arc-shaped. However, the various different test scenarios have one thing in common: the direction of the measuring antenna usually needs to be aligned with the center of the test coordinate, i.e. needs to be aligned with the position of the full vehicle to be tested.

In the practical test, it is often necessary to test in both the full anechoic chamber test system and the semi-anechoic chamber test system above. As for the two test systems mentioned above, it cannot perform the other type of test in one type of test system. Because in one type of test system, the position of the test coordinate is fixed, and the measuring antenna points to the center of the test coordinate when mounted. After the test system is calibrated, the direction of the measuring antenna is usually inconvenient to be adjusted during use. However, the test coordinates of the two test systems cannot be shared. Specifically, the test systems shown in FIG. 2 and FIG. 4 are taken as an example. In the full anechoic chamber test system shown in FIG. 2, the center of the circular arc-shaped rail is located at a position having a certain height (H1) above the center of the turntable, wherein this height is the height that the lifting machine can raise, and H1 may be more than 1 m in the related art. In the semi-anechoic chamber test system shown in FIG. 4, the center of the circular arc-shaped rail is located on the upper surface of the center of the turntable, and H1 is close to zero because the turntable is located on the bottom surface of the chamber. If the rising height of the lifting machine in the full anechoic chamber test system in FIG. 2 is set to 0, and the absorbing material on the ground is removed, the center of the circular arc-shaped rail is still located at a certain height above the center of the turntable, but the full vehicle to be tested can no longer be located at the center of the circle, that is, the test coordinate system shown in FIG. 3 cannot be realized, so that the test cannot be carried out. It is extremely difficult to move the circular arc-shaped rail downwardly to lower the center of the circle, because the circular arc-shaped rail is large in volume and weight, it needs to be firmly mounted and fixed in any type of chamber, and once it is built, the relative positional relationship is not easy to change, which means that the test system for the vehicle-mounted antenna in the related arts cannot conveniently switch between the full anechoic chamber test and the semi-anechoic chamber test.

### SUMMARY

In view of this, the object of the present disclosure is to provide a test system for the vehicle-mounted antenna, so as to solve the technical problem that the test system for the vehicle-mounted antenna in the related art cannot carry out both the full anechoic chamber test and the semi-anechoic chamber test.

Some embodiments of the present disclosure provide a test system for the vehicle-mounted antenna that can include: an anechoic chamber, a lifting table, a measuring antenna, and a reflecting plate, wherein
the anechoic chamber is configured to provide a full anechoic chamber test environment or a semi-anechoic chamber test environment;
the lifting table is fixedly arranged in the anechoic chamber, and configured to carry an full vehicle to be tested with the vehicle-mounted antenna and to drive the full vehicle to be tested to reach a preset height;
the measuring antenna is configured to communicate with the vehicle-mounted antenna, so as to obtain a wireless performance of the vehicle-mounted antenna; and
the reflecting plate is detachably connected to a bearing surface of the lifting table carrying the full vehicle to be tested, or the reflecting plate is integrally arranged with the bearing surface, wherein when the reflecting plate is integrally arranged with the bearing surface, the reflecting plate can extend and retract from the bearing surface, and the reflecting plate is configured to reflect electromagnetic waves.

In some embodiments, when the reflecting plate is detachably connected to the bearing surface of the lifting table carrying the full vehicle to be tested, the reflecting plate is mounted on the bearing surface under a semi-anechoic chamber test, and the reflecting plate is disassembled from the bearing surface under a full anechoic chamber test.

In some embodiments, when the reflecting plate is integrally arranged with the bearing surface, the reflecting plate extends from the bearing surface under the semi-anechoic chamber test, and the reflecting plate retracts into the bearing surface under the full anechoic chamber test.

In some embodiments, a boundary of an orthogonal projection of the lifting table may not exceed a boundary of an orthogonal projection of the full vehicle to be tested.

In some embodiments, the lifting table can further be configured to drive the full vehicle to be tested to rotate in a horizontal plane at the preset height.

In some embodiments, the lifting table can include:
a turntable, a lifting machine fixedly arranged above the turntable, and the bearing surface fixedly connected to the lifting machine; or
a lifting table body, a rotation machine built in the lifting table body, and a lifting machine built in the lifting table body, wherein the lifting table body is the bearing surface.

In some embodiments, one or a plurality of measuring antennas can be provided; and
the test system for the vehicle-mounted antenna can further include a scanning mechanism, wherein the scanning mechanism is configured to fixedly mount one or the plurality of measuring antennas and to drive the measuring antennas to move in a circular arc shape in a vertical direction, so that the measuring antennas can scan and communicate with the vehicle-mounted antenna in a circular arc-shaped track, so as to cooperate with a rotation of the lifting table to perform a spherical scanning test for the vehicle-mounted antenna.

In some embodiments, the scanning mechanism can include any one of the following: a circular arc-shaped rail, a rocker arm, and an industrial robotic arm.

In some embodiments, the plurality of measuring antennas can be provided; and
the test system for the vehicle-mounted antenna can further include a scanning mechanism, wherein the scanning mechanism is configured to fixedly mount the plurality of measuring antennas, so that the plurality of measuring antennas are distributed in a circular arc in a spatial position, so that the measuring antennas can scan and communicate with for the vehicle-mounted antenna in a circular arc-shaped track, so as to cooperate with a rotation of the lifting table to perform a spherical scanning test for the vehicle-mounted antenna.

In some embodiments, when the reflecting plate is detachably connected to the bearing surface, a form of the reflecting plate can include any one of the following: a form of an integral arrangement, and a form of splicing by sub-multiple reflecting plates.

In some embodiments, when the reflecting plate is detachably connected to the bearing surface, the reflecting plate is detachably connected to an upper surface of the bearing surface, or the reflecting plate is detachably connected to a side surface of the bearing surface.

In some embodiments, an area of the reflecting plate can extend outwardly from an outer boundary of the orthogonal projection of the full vehicle to be tested by a distance of at least three times the target wavelengths, wherein the target wavelength is a wavelength corresponding to a lowest operating frequency of the vehicle-mounted antenna.

In some embodiments, a material of the reflecting plate can include at least one of the following: a metal, carbon fiber, and composite materials.

In some embodiments, one or a plurality of reflecting plates can be provided, wherein when the plurality of reflecting plates are provided, the plurality of reflecting plates have different electromagnetic parameters for simulating different road surfaces.

In some embodiments, the anechoic chamber can include: a shielding body and an absorbing material, wherein
the absorbing material is distributed throughout all inner walls of the shielding body when the anechoic chamber provides a full anechoic chamber test environment; and
the absorbing material is arranged at least on an upper inner wall and a side inner wall of the shielding body when the anechoic chamber provides a semi-anechoic chamber test environment.

In some embodiments, the shielding body can be made of a metal plate for shielding external electromagnetic waves.

In embodiments of the present disclosure, a test system for the vehicle-mounted antenna is provided, and it can include: the anechoic chamber, the lifting table, the measuring antenna, and the reflecting plate, wherein the anechoic chamber is configured to provide the full anechoic chamber test environment or the semi-anechoic chamber test environment; the lifting table is fixedly arranged in the anechoic chamber, and configured to carry the full vehicle to be tested with the vehicle-mounted antenna and to drive the full vehicle to be tested to reach the preset height; the measuring antenna is configured to communicate with the vehicle-mounted antenna, so as to obtain the wireless performance of the vehicle-mounted antenna; and the reflecting plate is detachably connected to the bearing surface of the lifting table carrying the full vehicle to be tested, or the reflecting plate is integrally arranged with the bearing surface, wherein when the reflecting plate is integrally arranged with the bearing surface, the reflecting plate can extend and retract from the bearing surface, and the reflecting plate is configured to reflect the electromagnetic waves. From the above description, it can be seen that in the test system for the vehicle-mounted antenna in the present disclosure, when the reflecting plate is connected to the bearing surface, or when the reflecting plate extends from the bearing surface, the test system for the vehicle-mounted antenna can be used for the semi-anechoic chamber test; and when the reflecting plate is not connected to the bearing surface, or when the reflecting plate retracts into the bearing surface, the test system for the vehicle-mounted antenna can be used for the full anechoic chamber test. That is to say, the test system for the vehicle-mounted antenna of the present disclosure has functions of both the full anechoic chamber test and the semi-anechoic chamber test, and two functions can be conveniently switched by the way of disassembling/assembling or extending/retracting the reflecting plate. It is low in cost, and can adapt to more test requirements, so as to solve the technical problem that the test system for the vehicle-mounted antenna in the related art cannot carry out both the full anechoic chamber test and the semi-anechoic chamber test.

### BRIEF DESCRIPTION OF DRAWINGS

In order to more clearly illustrate the technical solutions in the embodiments of the present disclosure or in the related art, the drawings to be used in the description of the embodiments or related art will be briefly introduced below. It is obvious that the drawings in the following description are some embodiments of the present disclosure. For a person of ordinary skill in the art, other drawings can be obtained based on these drawings without inventive efforts.

FIG. 1 shows a schematic diagram of a test coordinate system provided by the embodiments of the present disclosure;

FIG. 2 shows a schematic diagram of a conventional full anechoic chamber test system provided by the embodiments of the present disclosure;

FIG. 3 shows a schematic diagram of an full vehicle to be tested in a test coordinate system provided by the embodiments of the present disclosure;

FIG. 4 shows a schematic diagram of a conventional semi-anechoic chamber test system provided by the embodiments of the present disclosure;

FIG. 5 shows a schematic structure diagram of a test system for a vehicle-mounted antenna provided by the embodiments of the present disclosure;

FIG. 6 shows a schematic diagram of a dimension relationship between a rectangular reflecting plate and an full vehicle to be tested provided by the embodiments of the present disclosure; and

FIG. 7 shows a schematic diagram of a dimension relationship between a circular reflecting plate and an full vehicle to be tested provided by the embodiments of the present disclosure.

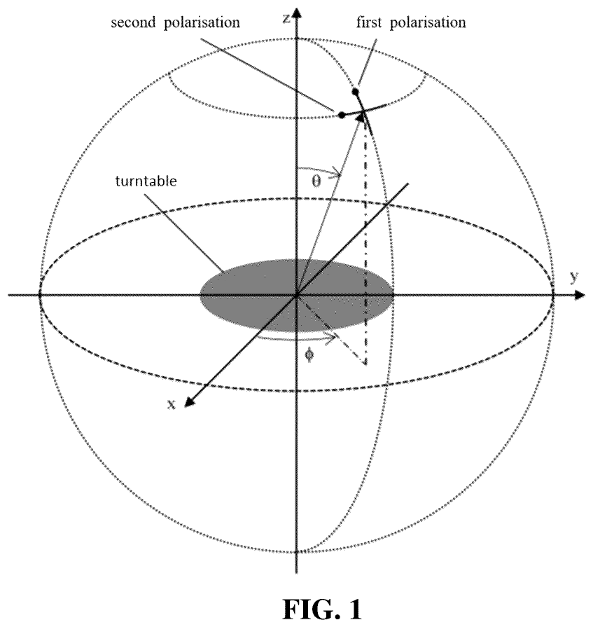

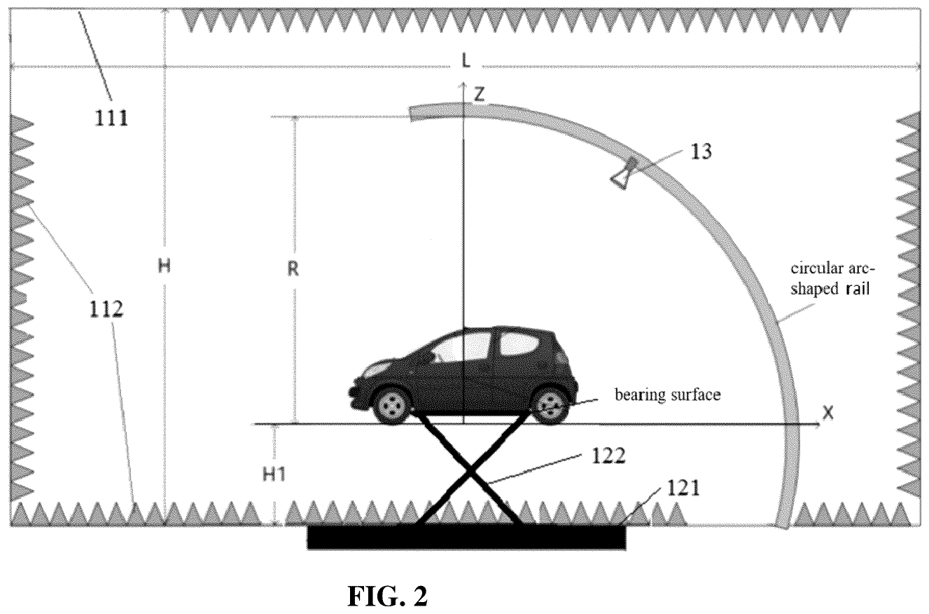

Reference numbers: 11—anechoic chamber; 12—lifting table; 13—measuring antenna; 14—reflecting plate; 15—scanning mechanism; 111—shielding body; 112—absorbing material; 121—turntable; 122—lifting machine; and 123—bearing surface.

### DETAILED DESCRIPTION OF EMBODIMENTS

The technical solutions in the embodiments of the present disclosure will be clearly and completely described below in conjunction with embodiments. It is clear that the embodiments described are only partial embodiments of the present disclosure, and not all of the embodiments. Based on the embodiments in the present disclosure, all other embodiments obtained by a person of ordinary skill in the art without inventive efforts shall fall within the scope of protection of the present disclosure.

In the conventional test system for the vehicle-mounted antenna, it cannot perform the other type of test in one type of test system, and building two test systems respectively will cost a lot of labor and capital.

In view of this, in the test system for the vehicle-mounted antenna provided in the present disclosure, when the reflecting plate is connected to the bearing surface, or when the reflecting plate extends from the bearing surface, the test system for the vehicle-mounted antenna can be used for the semi-anechoic chamber test; and when the reflecting plate is not connected to the bearing surface, or when the reflecting plate retracts into the bearing surface, the test system for the vehicle-mounted antenna can be used for the full anechoic chamber test. That is to say, the test system for the vehicle-mounted antenna of the present disclosure has functions of both the full anechoic chamber test and the semi-anechoic chamber test, and two functions can be conveniently switched by the way of disassembling/assembling or extending/retracting the reflecting plate. It is low in cost, and can adapt to more test requirements.

In order to facilitate the understanding of the embodiment, a test system for the vehicle-mounted antenna disclosed in the embodiment of the present disclosure will be described in detail first.

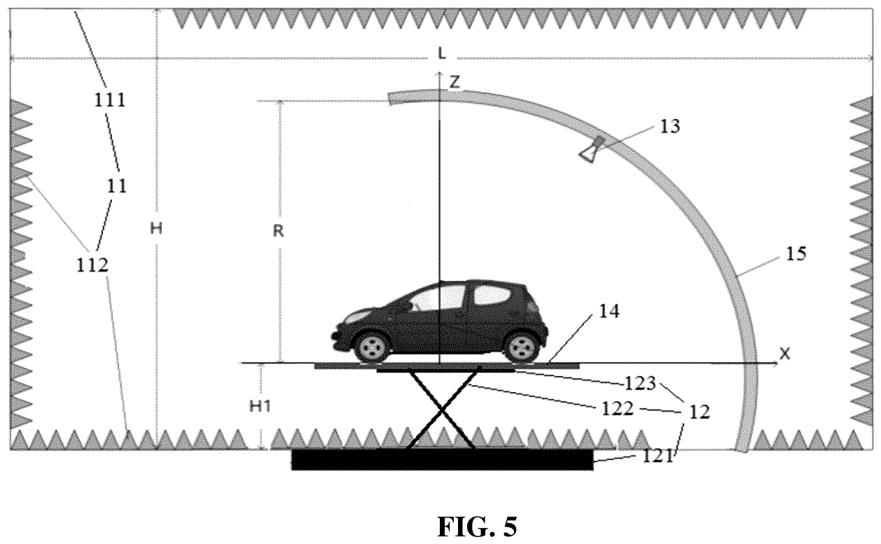

FIG. 5 is a schematic structure diagram of a test system for the vehicle-mounted antenna according to an embodiment of the present disclosure. As shown in FIG. 5, the test system for the vehicle-mounted antenna can include: an anechoic chamber 11, a lifting table 12, a measuring antenna 13, and a reflecting plate 14, wherein
the anechoic chamber 11 is configured to provide a full anechoic chamber test environment or a semi-anechoic chamber test environment;
the lifting table 12 is fixedly arranged in the anechoic chamber 11, the lifting table 12 can be configured to carry the full vehicle to be tested with the vehicle-mounted antenna and to drive the full vehicle to be tested to reach the preset height;
the measuring antenna 13 is configured to communicate with the vehicle-mounted antenna, so as to obtain the wireless performance of the vehicle-mounted antenna; and
the reflecting plate 14 is detachably connected to the bearing surface 123 of the lifting table 12 carrying the full vehicle to be tested, or the reflecting plate 14 is integrally arranged with the bearing surface 123, wherein when the reflecting plate 14 is integrally arranged with the bearing surface 123, the reflecting plate 14 can extend and retract from the bearing surface 123, and the reflecting plate 14 is configured to reflect the electromagnetic waves.

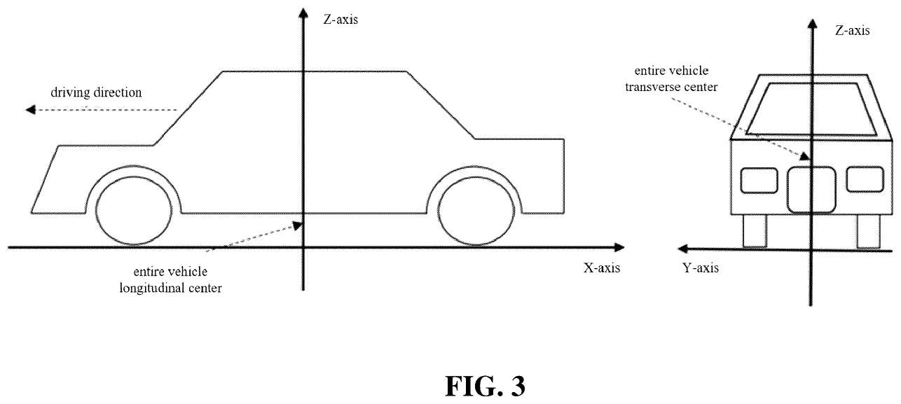

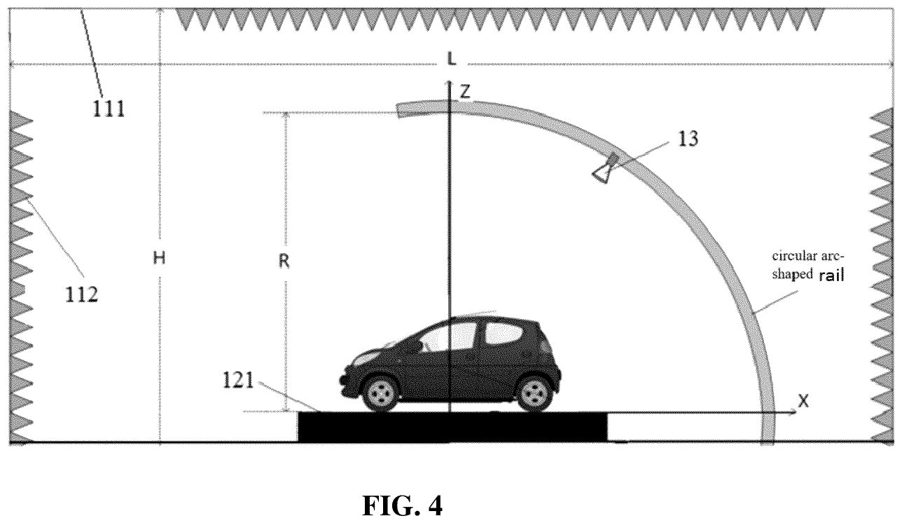

In the embodiment of the present disclosure, when the lifting table 12 drives the full vehicle to be tested to reach the preset height, the direction of the above measuring antenna 13 is aligned with the center of the test coordinate, i.e., is aligned with the position of the full vehicle to be tested, so as to satisfy the requirement of the coordinate system of the test system, as shown in FIG. 3. Specifically, according to some test specifications, if a sampling trajectory of the measuring antenna 13 is a circular arc, the center of the circular arc is located at the center of the bottom of the full vehicle to be tested; or according to some other test specifications, the center of the circular arc is located at the center of the whole of the full vehicle to be tested.

When the reflecting plate 14 is detachably connected to the bearing surface 123 of the lifting table 12 carrying the full vehicle to be tested, the reflecting plate 14 is mounted on the bearing surface 123 if it needs to carry out the semi-anechoic chamber test, and at this time, the reflecting plate 14 is configured to reflect electromagnetic waves, and it is equivalent to the ground in the conventional semi-anechoic chamber test system, so as to realize the semi-anechoic chamber test of the vehicle-mounted antenna; and the reflecting plate 14 is disassembled from the bearing surface 123 if it needs to carry out the full anechoic chamber test, which is the same as the conventional full anechoic chamber test system, so as to obtain a non-reflective environment, which can realize the full anechoic chamber test of the vehicle-mounted antenna.

When the reflecting plate 14 is integrally arranged with the bearing surface 123, the reflecting plate 14 extends from the bearing surface 123 if it needs to carry out the semi-anechoic chamber test, and at this time, the reflecting plate 14 is configured to reflect the electromagnetic waves, and it is equivalent to the ground in the conventional semi-anechoic chamber test system, so as to realize the semi-anechoic chamber test of the vehicle-mounted antenna; and the reflecting plate 14 retracts into the bearing surface 123 if it needs to carry out the full anechoic chamber test, which is the same as the conventional full anechoic chamber test system, so as to realize the full anechoic chamber test of the vehicle-mounted antenna.

It is to be noted that the above full vehicle to be tested can be a car to be tested, or a tank to be tested, etc., and the number of vehicle-mounted antennas carried by the full vehicle to be tested can be multiple or one, and the full vehicle to be tested in the embodiments of the present disclosure is illustrated as the car to be tested.

In embodiments of the present disclosure, a test system for the vehicle-mounted antenna is provided, including: the anechoic chamber 11, the lifting table 12, the measuring antenna 13, and the reflecting plate 14, wherein the anechoic chamber 11 is configured to provide the full anechoic chamber test environment or the semi-anechoic chamber test environment; the lifting table 12 is fixedly arranged in the anechoic chamber 11, and configured to carry the full vehicle to be tested with the vehicle-mounted antenna and to drive the full vehicle to be tested to reach the preset height; the measuring antenna 13 is configured to communicate with the vehicle-mounted antenna, so as to obtain the wireless performance of the vehicle-mounted antenna; and the reflecting plate 14 is detachably connected to the bearing surface 123 of the lifting table 12 carrying the full vehicle to be tested, or the reflecting plate 14 is integrally arranged with the bearing surface 123, wherein when the reflecting plate 14 is integrally arranged with the bearing surface 123, the reflecting plate 14 can extend and retract from the bearing surface 123, and the reflecting plate 14 is configured to reflect the electromagnetic waves. From the above description, it can be seen that in the test system for the vehicle-mounted antenna in the present disclosure, when the reflecting plate 14 is connected to the bearing surface 123, or when the reflecting plate 14 extends from the bearing surface 123, the test system for the vehicle-mounted antenna can be used for the semi-anechoic chamber test; and when the reflecting plate 14 is not connected to the bearing surface 123, or when the reflecting plate 14 retracts into the bearing surface 123, the test system for the vehicle-mounted antenna can be used for the full anechoic chamber test. That is to say, the test system for the vehicle-mounted antenna of the present disclosure has functions of both the full anechoic chamber test and the semi-anechoic chamber test, and two functions can be conveniently switched by the way of disassembling/assembling or extending/retracting the reflecting plate 14. It is low in cost, and can adapt to more test requirements, so as to solve the technical problem that the test system for the vehicle-mounted antenna in the related art cannot carry out both the full anechoic chamber test and the semi-anechoic chamber test.

The above contents provide a brief description of the structure of the test system for the vehicle-mounted antenna of the present disclosure, and the specific contents involved therein are described in detail below.

In an optional embodiment of the present disclosure, referring to FIG. 5, the anechoic chamber 11 includes: a shielding body 111 and an absorbing material 112, wherein
the absorbing material 112 is distributed throughout all inner walls of the shielding body 111 when the anechoic chamber 11 provides the full anechoic chamber test environment; and
the absorbing material 112 is arranged at least on an upper inner wall and a side inner wall of the shielding body 111 when the anechoic chamber 11 provides the semi-anechoic chamber test environment.

Specifically, the shielding body 111 is usually made of a metal plate for shielding external electromagnetic waves. When it is the full anechoic chamber test environment, the absorbing material 112 is distributed throughout all inner walls of the shielding body 111 for absorbing the energy of the electromagnetic waves; and when it is the semi-anechoic chamber test environment, the absorbing material 112 is arranged at least on the upper inner wall and the side inner wall of the shielding body 111. Therefore, when the semi-anechoic chamber test environment is switched to the full anechoic chamber test environment, the absorbing material 112 is necessary to be arranged on the bottom inner wall if the bottom inner wall of the original shielding body 112 is not provided with the absorbing material 111. When the full anechoic chamber test environment is switched to the semi-anechoic chamber test environment, the absorbing material 112 is distributed throughout all inner walls of the shielding body 111. The semi-anechoic chamber test will not be affected, because the reflecting plate 14 simulates the ground environment required for the test under this type of test.

In an optional embodiment, a boundary of an orthogonal projection of the lifting table 12 does not exceed a boundary of an orthogonal projection of the full vehicle to be tested.

Specifically, when the boundary of the orthogonal projection of the lifting table 12 exceeds the boundary of the orthogonal projection of the full vehicle to be tested, the lifting table 12 will bring about a certain electromagnetic wave reflection during the full anechoic chamber test, which may lead to a decrease in the performance of the quiet zone, and thus affect the accuracy of the test. Therefore, through limiting that the boundary of the orthogonal projection of the lifting table 12 does not exceed the boundary of the orthogonal projection of the full vehicle to be tested, the influence of the electromagnetic wave reflection since the lifting table 12 is too large can be avoided, so as to ensure the accuracy of the test result.

In an optional embodiment of the present disclosure, the lifting table is further configured to drive the full vehicle to be tested to rotate in a horizontal plane at the preset height.

In an optional embodiment of the present disclosure, referring to FIG. 5, the lifting table 12 includes: a turntable 121, a lifting machine 122 fixedly arranged above the turntable 121, and the bearing surface 123 fixedly connected to the lifting machine 122; or
a lifting table body, a rotation machine built in the lifting table body, and a lifting machine 122 built in the turntable body, wherein the lifting table body is the bearing surface 123.

Specifically, in the above first structure of the lifting table 12, the turntable 121 (one-dimensional plane turntable) can drive the full vehicle to be tested to rotate on the horizontal plane; the lifting machine 122 can drive the full vehicle to be tested to reach the preset height; and the bearing surface 123 is configured to bear the full vehicle to be tested. In this structure, the lifting machine 122 generally existed in the related art can be additionally arranged on the one-dimensional plane turntable 121 generally existed in the related art, so as to obtain the lifting table 12. In the above second structure of the lifting table 12, the lifting table 12 is integrally arranged, and can realize the same function.

In an optional embodiment of the present disclosure, one or a plurality of measuring antennas 13 is provided; and
the test system for the vehicle-mounted antenna can further include a scanning mechanism 15, wherein the scanning mechanism 15 is configured to fixedly mount one or the plurality of measuring antennas 13 and to drive the measuring antennas 13 to move in a circular arc shape in a vertical direction, so that the measuring antennas 13 carries out a scanning communication for the vehicle-mounted antenna in a circular arc-shaped track, so as to cooperate with a rotation of the lifting table 12 to perform a spherical scanning test for the vehicle-mounted antenna.

Specifically, the above spherical scanning test does not need to perform for the full spherical surface, but can be partial spherical surface according to the test requirements, e.g., an upper hemisphere surface. As an example, when the circular arc-shaped movement range of the measuring antenna 13 is 90°, the scanning test on the upper hemisphere surface of the vehicle-mounted antenna can be realized in conjunction with the 360° rotation of the lifting table 12 on the horizontal plane. As another example, when the circular arc-shaped movement range of the measuring antenna 13 is 180°, the scanning test on the upper hemisphere surface of the vehicle-mounted antenna can be realized in conjunction with the 180° rotation of the lifting table 12 on the horizontal plane.

Optionally, the above scanning mechanism 15 includes any one of the following: a circular arc-shaped rail, a rocker arm, and an industrial robotic arm (FIG. 5 shows that the scanning mechanism 15 is a circular arc-shaped rail). When the scanning mechanism 15 is the circular arc-shaped rail, the measuring antenna 13 is mounted on the circular arc-shaped rail and can move along the circular arc-shaped rail; when the scanning mechanism 15 is the rocker arm, the measuring antenna 13 is mounted on the rocker arm, and the measuring antenna 13 moves in a circular arc by the driving of the turntable motor of the rocker arm; when the scanning mechanism 15 is the industrial robotic arm, the measuring antenna 13 is mounted on the industrial robotic arm, and the industrial robotic arm drives the measuring antenna 13 to move in the circular arc. Optionally, the measuring antenna 13 is located in a near-field radiation range of the full vehicle to be tested, so as to perform a near-field spherical scanning test of the vehicle-mounted antenna.

In an optional embodiment of the present disclosure, the plurality of measuring antennas 13 are provided; and

the test system for the vehicle-mounted antenna can further include the scanning mechanism 15, wherein the scanning mechanism 15 is configured to fixedly mount the plurality of measuring antennas 13, so that the plurality of measuring antennas 13 are distributed in a circular arc in a spatial position, so that the measuring antennas 13 scans and communicates with the vehicle-mounted antenna in a circular arc-shaped track, so as to cooperate with a rotation of the lifting table 12 to perform a spherical scanning test for the vehicle-mounted antenna.

In an optional embodiment of the present disclosure, when the reflecting plate 14 is detachably connected to the bearing surface 123, a form of the reflecting plate 14 includes any one of the following: a form of an integral arrangement, and a form of splicing by multiple sub-reflecting plates 14.

Specifically, the above detachable connection can be a snap connection, or can be a hinge connection, and the embodiments of the present disclosure do not specifically limit the manner of the above detachable connection. Additionally, the reflecting plate 14 can be a reflecting plate 14 integrally arranged, or can be an integral reflecting plate 14 by splicing. The whole reflecting plate 14 can be a plane parallel to the bearing surface 123.

In an optional embodiment of the present disclosure, when the reflecting plate 14 is detachably connected to the bearing surface 123, the reflecting plate 14 is detachably connected to an upper surface of the bearing surface 123, or the reflecting plate 14 is detachably connected to a side surface of the bearing surface 123 (FIG. 5 shows a schematic diagram of the reflecting plate 14 being detachably connected to the upper surface of the bearing surface 123).

Specifically, the reflecting plate 14 can be mounted on the upper surface of the bearing surface 123, i.e., located between the full vehicle to be tested and the upper surface of the bearing surface 123 during the test; or it can be mounted on the side surface of the bearing surface 123, and the upper surface of the reflecting plate 14 is flush to the bearing surface 123, so as to conform to a relative position between the simulated ground and the full vehicle to be tested. Mounting on the side surface has the following beneficial effects: the reflecting plate 14 can also be disassembled and assembled when the full vehicle to be tested is placed on the bearing surface 123, and it does not need to move the full vehicle to be tested down from the bearing surface 123, and then the reflecting plate 14 is disassembled or assembled. Therefore, it saves the test time and facilitates quick switching between two test functions, and the reflecting plate 14 can be quickly switched to simulate different road surfaces.

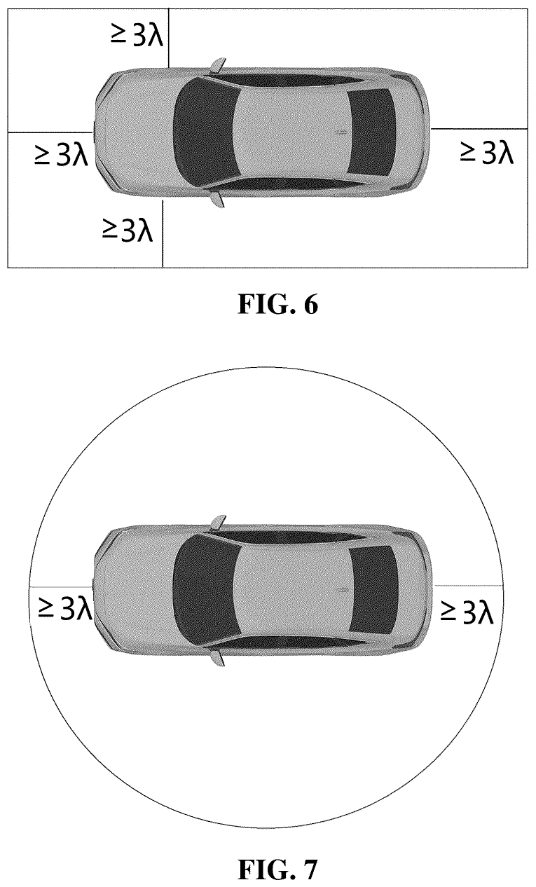

In an optional embodiment of the present disclosure, as shown in FIG. 6 and FIG. 7, an area of the reflecting plate 14 extends outwardly from an outer boundary of the orthogonal projection of the full vehicle to be tested by a distance of at least three times the target wavelengths, wherein the target wavelength is a wavelength corresponding to a lowest operating frequency of the vehicle-mounted antenna.

Specifically, the larger the reflecting plate 14 is, the better the reflecting effect for the electromagnetic waves will be. After many tests by inventors, when the area of the reflecting plate 14 extends outwardly from the outer boundary of the orthogonal projection of the full vehicle to be tested by a distance of at least three times the target wavelengths, it can obtain a test result (e.g., the radiation antenna pattern) with better accuracy. If it is desired to obtain a more accurate test result, the area of the reflecting plate 14 can be set to be larger, but when the area of the reflecting plate 14 extends outwardly to a distance of six target wavelengths from the outer boundary of the orthogonal projection of the full vehicle to be tested, if the area is further increased, the effect on the test result can be ignored. Therefore, during the actual test, if the lowest operating frequency of the vehicle-mounted antenna is higher; its corresponding target wavelength is shorter; and the accuracy of the test results is required to be higher, it can be extended outwardly by six target wavelengths to ensure the test accuracy. However, if the lowest operating frequency of the vehicle-mounted antenna is low and its corresponding target wavelength is long, considering the cost and the difficulty of engineering realization, it can sacrifice a certain degree of precision and only extend outwardly by the distance of three target wavelengths. Because in this condition, if it extends outwardly by the distance of six target wavelengths, the area of the reflecting plate 14 will be very large and not easy to realize. It can be set according to the actual test requirements.

In an optional embodiment of the present disclosure, a material of the reflecting plate 14 includes at least one of the following: a metal, carbon fiber, and composite materials.

Specifically, the reflecting plate 14 can be made of the carbon fiber material, wherein the reflection characteristic of the carbon fiber material to the electromagnetic waves is the same as that of the metal, and it has a light weight, so as to be used to simulate metal. The reflecting plate 14 can further be made of composite materials, wherein the reflection characteristic of the composite materials to the electromagnetic wave can be used to simulate the reflection characteristics of the concrete road surface or gravel road surface to the electromagnetic wave.

In an optional embodiment of the present disclosure, one or a plurality of reflecting plates 14 are provided, wherein when the plurality of reflecting plate 14 are provided, the plurality of reflecting plates 14 have different electromagnetic parameters for simulating different road surfaces, and different reflecting plates 14 can be mounted or extended according to the test requirements.

In an optional embodiment of the present disclosure, a shape of the reflecting plate 14 includes at least one of the following: a circle, a rectangle, a square, and a polygon.

As for the test system for the vehicle-mounted antenna recorded by the present disclosure, the full vehicle to be tested can be used to perform the test under any one test function according to the test requirements. Two test functions are schematically illustrated below.

In the full anechoic chamber test, the reflecting plate 14 is disassembled from the bearing surface 123, or the reflecting plate 14 is retracted into the bearing surface 123, and the lifting table 12 lifts the full vehicle to be tested to the preset height, wherein
when the anechoic chamber 11 is the full anechoic chamber test environment, the absorbing material 112 has been arranged on the bottom of the shielding body 111, which satisfies the test environment and reaches the working state of the full anechoic chamber; and when the anechoic chamber 11 is the semi-anechoic chamber test environment, the test environment can be satisfied by arranging the absorbing material 112 on the bottom.

In the semi-anechoic chamber test, the reflecting plate 14 is mounted on the bearing surface 123, or the reflecting plate 14 is extended from the bearing surface 123, and the lifting table 12 lifts the full vehicle to be tested to the preset height, wherein
when the anechoic chamber 11 is the full anechoic chamber test environment, the absorbing material 112 has been arranged on the shielding body 111, and the absorbing material 112 arranged on the bottom does not affect the semi-anechoic chamber test, because the reflecting plate 14 simulates the ground environment required for the test at this time; and when the anechoic chamber 11 is the semi-anechoic chamber test environment, it satisfies the test environment.

In an optional embodiment of the present disclosure, the test system for the vehicle-mounted antenna can perform the performance test for the vehicle-mounted antenna, including: antenna pattern, antenna gain, antenna efficiency, etc. It can further test the overall performance of the vehicle-mounted antenna and transceiver, such as equivalent isotropic radiated power (EIRP), effective isotropic sensitivity (EIS), total radiated power (TRP), and total radiated sensitivity (TRS), etc.

The test system for the vehicle-mounted antenna of the present disclosure is the same as an ordinary full anechoic chamber under the test function of the full anechoic chamber. Under the test function of the semi-anechoic chamber, the added reflecting plate 14 is located between the full vehicle to be tested and the bearing surface 123, and the reflecting plate 14 simulates the ground of the semi-anechoic chamber. Since the size of the reflecting plate 14 is larger than the size of the orthogonal projection of the full vehicle to be tested (the orthogonal projection of the full vehicle to be tested is completely located in the reflecting plate 14), and the size of the reflecting plate 14 is large enough relative to the operating frequency of the vehicle-mounted antenna, the main downward radiation energy of the vehicle-mounted antenna can be almost completely reflected by the reflecting plate 14. In this case, the reflecting plate 14 can well simulate the reflection of the ground to the electromagnetic waves of the vehicle-mounted antenna in the semi-anechoic chamber.

The reflecting plate 14 can be made of the lightweight carbon fiber material, and at the same time, can be realized by adopting multiple-plate splicing method, which is convenient to assemble or disassemble one by one, and thus can be conveniently converted between two test functions.

The test system for the vehicle-mounted antenna of the present disclosure has two test functions. One test system for the vehicle-mounted antenna provided by the present disclosure can adapt to more test requirements; has a lower cost; can be easily switched between two test functions; and is a multifunctional and low-cost test solution for the vehicle-mounted antenna.

Additionally, in the description of the embodiments of the present disclosure, unless other expressly specifications and limitations, the terms “mount”, “connect”, and “link” are to be understood in a broad sense, e.g. it can be a fixed connection, a detachable connection, or an integral connection; it can be a mechanical connection or an electrical connection; and it can be a direct connection, an indirect connection through an intermediate medium, or a communication inside two components. For a person of ordinary skill in the art, the specific meaning of the above terms in the present disclosure can be understood according to specific situations.

In the description of the present disclosure, it should be noted that orientations or positional relationships indicated by terms, such as “center”, “up”, “down”, “left”, “right”, “vertical”, “horizontal”, “inside”, and “outside”, etc., are the orientations or positional relationships based on the drawings, which are only to facilitate the description of the present disclosure and simplify the description, and are not to indicate or imply that the device or element referred to must have a particular orientation, or be constructed and operated with a particular orientation, and therefore cannot to be understood as limitations of the present disclosure. Additionally, the terms “first”, “second”, and “third”, etc., are used only for descriptions, and are not to be understood as indicating or implying a relative importance.

Finally, it should be noted that the above embodiments are only used to illustrate the technical solutions of the present disclosure, and not to restrict it. Although the present disclosure is described in detail with reference to each foregoing embodiments, it should be understood by persons of ordinary skill in the art that they may still modify the technical solutions described in the foregoing embodiments or make equivalent substitutions for some or all of the technical features; and these modifications or substitutions do not take the essence of the corresponding technical solutions out of the scope of the technical solutions in each embodiment of the present disclosure.

### INDUSTRIAL APPLICABILITY

The present disclosure provides a test system for the vehicle-mounted antenna. In the test system, when the reflecting plate is connected to the bearing surface, or when the reflecting plate extends from the bearing surface, the test system for the vehicle-mounted antenna can be used for the semi-anechoic chamber test; and when the reflecting plate is not connected to the bearing surface, or when the reflecting plate retracts into the bearing surface, the test system for the vehicle-mounted antenna can be used for the full anechoic chamber test. That is to say, the test system for the vehicle-mounted antenna of the present disclosure has functions of both the full anechoic chamber test and the semi-anechoic chamber test, and two functions can be conveniently switched by the way of disassembling/assembling or extending/retracting the reflecting plate. It is low in cost, and can adapt to more test requirements, so as to solve the technical problem that the test system for the vehicle-mounted antenna in the related art cannot carry out both the full anechoic chamber test and the semi-anechoic chamber test.

Furthermore, it will be appreciated that the test system for test system for the vehicle-mounted antenna of the present disclosure is reproducible, and can be applied in a variety of industrial applications. For example, the test system for the vehicle-mounted antenna of the present disclosure can be applied in the technical field of the communication.

1. A test system for a vehicle-mounted antenna, comprising: an anechoic chamber, a lifting table, at least one measuring antenna, and a reflecting plate, wherein the anechoic chamber is configured to provide a full anechoic chamber test environment or a semi-anechoic chamber test environment;
the lifting table is fixedly arranged in the anechoic chamber, and configured to carry a full vehicle to be tested with the vehicle-mounted antenna and to drive the full vehicle to be tested to reach a preset height;
the at least one measuring antenna is configured to communicate with the vehicle-mounted antenna, so as to obtain a wireless performance of the vehicle-mounted antenna; and
the reflecting plate is detachably connected to a bearing surface of the lifting table carrying the full vehicle to be tested, or the reflecting plate is integrally arranged with the bearing surface, wherein when the reflecting plate is integrally arranged with the bearing surface, the reflecting plate can extend and retract from the bearing surface, and the reflecting plate is configured to reflect electromagnetic waves.

2. The test system for the vehicle-mounted antenna according to claim 1, wherein when the reflecting plate is detachably connected to the bearing surface of the lifting table carrying the full vehicle to be tested, the reflecting plate is mounted on the bearing surface under a semi-anechoic chamber test, and the reflecting plate is disassembled from the bearing surface under a full anechoic chamber test.

3. The test system for the vehicle-mounted antenna according to claim 1, wherein when the reflecting plate is integrally arranged with the bearing surface, the reflecting plate extends from the bearing surface under a semi-anechoic chamber test, and the reflecting plate retracts into the bearing surface under a full anechoic chamber test.

4. The test system for the vehicle-mounted antenna according to claim 1, wherein a boundary of an orthogonal projection of the lifting table does not exceed a boundary of an orthogonal projection of the full vehicle to be tested.

5. The test system for the vehicle-mounted antenna according to claim 1, wherein the lifting table is further configured to drive the full vehicle to be tested to rotate in a horizontal plane at the preset height.

6. The test system for the vehicle-mounted antenna according to claim 5, wherein the lifting table comprises:
a turntable, a lifting machine fixedly arranged above the turntable, and the bearing surface fixedly connected to the lifting machine; or
a lifting table body, a rotation machine built in the lifting table body, and a lifting machine built in the lifting table body, wherein the lifting table body is the bearing surface.

7. The test system for the vehicle-mounted antenna according to claim 5, wherein one or a plurality of measuring antennas are provided; and
the test system for the vehicle-mounted antenna further comprises a scanning mechanism, wherein the scanning mechanism is configured to fixedly mount one or the plurality of measuring antennas and to drive the measuring antennas to move in a circular arc shape in a vertical direction, so that the measuring antennas scan and communicate with the vehicle-mounted antenna in a circular arc-shaped track, so as to cooperate with a rotation of the lifting table to perform a spherical scanning test for the vehicle-mounted antenna.

8. The test system for the vehicle-mounted antenna according to claim 7, wherein the scanning mechanism comprises any one of a circular arc-shaped rail, a rocker arm, or an industrial robotic arm.

9. The test system for the vehicle-mounted antenna according to claim 5, wherein a plurality of measuring antennas are provided; and
the test system for the vehicle-mounted antenna can further comprise a scanning mechanism, wherein the scanning mechanism is configured to fixedly mount the plurality of measuring antennas, so that the plurality of measuring antennas are distributed in a circular arc in a spatial position, so that the measuring antennas carry out a scanning communication for the vehicle-mounted antenna in a circular arc-shaped track, so as to cooperate with a rotation of the lifting table to perform a spherical scanning test for the vehicle-mounted antenna.

10. The test system for the vehicle-mounted antenna according to claim 1, wherein when the reflecting plate is detachably connected to the bearing surface, a form of the reflecting plate comprises any one of a form of an integral arrangement, and a form of splicing by multiple sub-reflecting plates.

11. The test system for the vehicle-mounted antenna according to claim 1, wherein when the reflecting plate is detachably connected to the bearing surface, the reflecting plate is detachably connected to an upper surface of the bearing surface, or the reflecting plate is detachably connected to a side surface of the bearing surface.

12. The test system for the vehicle-mounted antenna according to claim 1, wherein an area of the reflecting plate extends outwardly from an outer boundary of an orthogonal projection of the full vehicle to be tested by a distance of at least three times the target wavelengths, wherein the target wavelength is a wavelength corresponding to a lowest operating frequency of the vehicle-mounted antenna.

13. The test system for the vehicle-mounted antenna according to claim 1, wherein a material of the reflecting plate comprises at least one of a metal, carbon fiber, and a composite material.

14. The test system for the vehicle-mounted antenna according to claim 1, wherein one or a plurality of reflecting plates are provided, wherein when the plurality of reflecting plates are provided, the plurality of reflecting plates have different electromagnetic parameters for simulating different road surfaces.

15. The test system for the vehicle-mounted antenna according to claim 1, wherein the anechoic chamber comprises: a shielding body and an absorbing material, wherein
the absorbing material is distributed throughout all inner walls of the shielding body when the anechoic chamber provides the full anechoic chamber test environment; and
the absorbing material is arranged at least on an upper inner wall and a side inner wall of the shielding body when the anechoic chamber provides the semi-anechoic chamber test environment.

16. The test system for the vehicle-mounted antenna according to claim 15, wherein the shielding body is made of a metal plate for shielding external electromagnetic waves.

17. The test system for the vehicle-mounted antenna according to claim 2, wherein a boundary of an orthogonal projection of the lifting table does not exceed a boundary of an orthogonal projection of the full vehicle to be tested.

18. The test system for the vehicle-mounted antenna according to claim 2, wherein the lifting table is further configured to drive the full vehicle to be tested to rotate in a horizontal plane at the preset height.

19. The test system for the vehicle-mounted antenna according to claim 6, wherein one or a plurality of measuring antennas are provided; and
the test system for the vehicle-mounted antenna further comprises a scanning mechanism, wherein the scanning mechanism is configured to fixedly mount one or the plurality of measuring antennas and to drive the measuring antennas to move in a circular arc shape in a vertical direction, so that the measuring antennas scan and communicate with the vehicle-mounted antenna in a circular arc-shaped track, so as to cooperate with a rotation of the lifting table to perform a spherical scanning test for the vehicle-mounted antenna.

20. The test system for the vehicle-mounted antenna according to claim 6, wherein a plurality of measuring antennas are provided; and
the test system for the vehicle-mounted antenna can further comprise a scanning mechanism, wherein the scanning mechanism is configured to fixedly mount the plurality of measuring antennas, so that the plurality of measuring antennas are distributed in a circular arc in a spatial position, so that the measuring antennas carry out a scanning communication for the vehicle-mounted antenna in a circular arc-shaped track, so as to cooperate with a rotation of the lifting table to perform a spherical scanning test for the vehicle-mounted antenna.
